(19) United States
(12) Patent Application Publication
(10) Pub. No.: US 2019/0244937 A1
(43) Pub. Date: Aug. 8, 2019

(54) DISPLAY DEVICE AND METHOD FOR MANUFACTURING THE SAME, AND LIGHT-EMITTING DEVICE AND METHOD FOR MANUFACTURING THE SAME

(71) Applicant: DEXERIALS CORPORATION, Tokyo (JP)

(72) Inventors: Keiji HONJO, Tochigi (JP); Hidetsugu NAMIKI, Tochigi (JP); Yasuyuki HIGUCHI, Tochigi (JP)

(73) Assignee: DEXERIALS CORPORATION, Tokyo (JP)

(21) Appl. No.: 16/081,673

(22) PCT Filed: Feb. 20, 2017
(86) PCT No.: PCT/JP2017/006199

§ 371 Date: Aug. 31, 2018

(30) Foreign Application Priority Data
Mar. 2, 2016 (JP) 2016-040529

(51) Int. Cl. H01L 25/075

(52) U.S. Cl. CPC H01L 25/0753

(57) ABSTRACT

A display device which can achieve increased brightness and resolution and a method for manufacturing the same as well as a light-emitting device and a method for manufacturing the same are provided. The device includes a plurality of light-emitting elements having a first face, arranged in units of subpixels, and having at least one of a first electrically conducting electrode and second electrically conducting electrode on the first face, a substrate having an electrode corresponding to the electrode on the first face of the plurality of light-emitting elements, an anisotropic conductive film providing an anisotropic conductive connection between the electrode on the first face of the plurality of light-emitting elements and the electrode of the substrate, and a wavelength conversion member converting a wavelength of light from the light-emitting elements in units of subpixels.

### TECHNICAL FIELD

The present disclosure relates to a display device having a plurality of light-emitting elements and a method for manufacturing the same as well as a light-emitting device and a method for manufacturing the same. This application claims priority based on Japanese Patent Application No. 2016-040529 filed on Mar. 2, 2016, the entire contents of which are hereby incorporated by reference.

### BACKGROUND ART

Micro LED (Light Emitting Diode) displays in which minute light-emitting elements are arrayed on a substrate have been proposed. Micro LED displays have the potential to obviate backlights required by conventional liquid crystal displays, which would enable thinner displays as well as widened color gamuts, increased resolutions, and reduced energy consumption.

PLT 1 discloses picking up and conveying each of red, blue, and green light-emitting elements respectively before aligning and mounting the red, blue, and green light-emitting elements and finally metal-bonding the light-emitting elements to a substrate.

Furthermore, NPL 1 discloses forming light-emitting elements on a wafer, electrically connecting p-electrodes and n-electrodes adjacent to each other in a lattice pattern using metal wires, and coating a resin containing red, blue, and green quantum dot phosphors thereon.

### CITATION LIST

### Patent Literature

PLT 1: Japanese Translation of PCT International Application Publication No. JP- T-2015-500562

### Non-Patent Literature

NPL 1: Resonant-enhanced full-color emission of quantum-dot-based micro LED display technology, Optics Express, Vol.23, Issue 25, pp. 32504-32515 (2015).

### SUMMARY OF INVENTION

### Technical Problem

In the method of PLT 1, long mounting times cause extremely poor throughput and misalignment leads to unsatisfactory yields. Moreover, picking up and aligning the light-emitting elements widens gaps between the light-emitting elements, which is problematic in view of increasing resolution.

Furthermore, with the method of NPL 1, because numerous wire bonds are required, throughput is poor, and wire bonds to microelectrodes lead to poor yields. Moreover, because electrodes and wires are present above the light emitting surface, light extraction efficiency is lowered, making it difficult to achieve high brightness.

In view of such conventional circumstances, an object of the present disclosure is to provide a display device which can achieve increased brightness and resolution and a method for manufacturing the same as well as a light-emitting device and a method for manufacturing the same.

### Solution to Problem

As a result of intensive studies, the present inventors have found that by using an anisotropic conductive adhesive, a plurality of light emitting elements can be batch-mounted in an arrangement formed on a wafer, and it is possible to improve brightness and resolution.

Thus, a display device according to the present disclosure includes a plurality of light-emitting elements having a first face, arranged in units of subpixels constituting a pixel, and having at least one of a first electrically conducting electrode and a second electrically conducting electrode on the first face, a substrate having an electrode corresponding to the electrode on the first face of the plurality of light-emitting elements, an anisotropic conductive film providing an anisotropic conductive connection between the electrode on the first face of the plurality of light-emitting elements and the electrode of the substrate, and a wavelength conversion member converting a wavelength of light from the light-emitting elements in units of subpixels.

Furthermore, a method for manufacturing a display device according to the present disclosure includes a connecting step of compression bonding a wafer on which a plurality of light-emitting elements having a first face are arranged in units of subpixels constituting a pixel, the plurality of light-emitting elements having at least one of a first electrically conducting electrode and a second electrically conducting electrode on the first face, to a substrate having an electrode corresponding to the electrode on the first face of the plurality of light-emitting elements via an anisotropic conductive adhesive providing an anisotropic conductive connection between the electrode on the first face of the plurality of light-emitting elements and the electrode of the substrate, and a member arranging step of arranging a wavelength conversion member converting a wavelength of light from the light-emitting elements in units of subpixels.

Furthermore, a light-emitting device according to the present disclosure includes a plurality of light-emitting elements having a first face, arranged in an array formed on a wafer, and having at least one of a first electrically conducting electrode and a second electrically conducting electrode on the first face, a substrate having an electrode corresponding to the electrode on the first face of the plurality of light-emitting elements, and an anisotropic conductive film providing an anisotropic conductive connection between the electrode on the first face of the plurality of light-emitting elements and the electrode of the substrate.

Moreover, a method for manufacturing a light-emitting device according to the present disclosure includes compression bonding a wafer on which a plurality of light-emitting elements having a first face are arrayed, the plurality of light-emitting elements having at least one of a first electrically conducting electrode and a second electrically conducting electrode on the first face, to a substrate having an electrode corresponding to the electrode on the first face of the plurality of light-emitting elements via an anisotropic conductive adhesive providing an anisotropic conductive connection between the electrode on the first face of the plurality of light-emitting elements and the electrode of the substrate.

### Advantageous Effects of Invention

According to the present disclosure, by using an anisotropic conductive adhesive, a plurality of light-emitting elements can be batch-mounted in an arrangement formed on a wafer and brightness and resolution can be improved.

### BRIEF DESCRIPTION OF DRAWINGS

FIG. 1 is a cross-sectional view schematically illustrating a display device according to a first embodiment.

FIG. 2 is a cross-sectional view schematically illustrating an example of one mounted light-emitting element.

FIG. 3(A) is a cross-sectional view schematically illustrating a light-emitting element on a wafer, and FIG. 3(B) is a cross-sectional view schematically illustrating a step of connecting a light-emitting element and a substrate.

FIG. 4 is a cross-sectional view schematically illustrating a member arranging step according to a first embodiment, FIG. 4(A) illustrates a step of removing the wafer, and FIG. 4(B) illustrates a step of forming a phosphor layer.

FIG. 5 is a cross-sectional view schematically illustrating a display device according to a second embodiment.

FIG. 6 is a cross-sectional view schematically illustrating a member arranging step according to a second embodiment.

FIG. 7 is a cross-sectional view schematically illustrating a display device according to a third embodiment.

FIG. 8 is a cross-sectional view schematically illustrating a member arranging step according to a third embodiment.

FIG. 9 is a cross-sectional view schematically illustrating a display device according to a fourth embodiment.

FIG. 10 is a cross-sectional view schematically illustrating a member arranging step according to a fourth embodiment, FIG. 10(A) illustrates a step of forming a phosphor layer, and FIG. 10(B) illustrates a step of arranging a color filter.

FIG. 11 is a cross-sectional view schematically illustrating a display device according to a fifth embodiment.

FIG. 12 is a cross-sectional view schematically illustrating a member arranging step according to a fifth embodiment, FIG. 12(A) illustrates a step of forming a phosphor layer, and FIG. 12(B) illustrates a step of arranging a color filter.

FIG. 13 is a cross-sectional view schematically illustrating a display device according to a sixth embodiment.

FIG. 14 is a cross-sectional view schematically illustrating a member arranging step according to a sixth embodiment.

FIG. 15 is a cross-sectional view schematically illustrating a display device according to a seventh embodiment.

FIG. 16 is a cross-sectional view schematically illustrating a member arranging step according to a seventh embodiment.

FIG. 17 is a cross-sectional view schematically illustrating a display device according to an eighth embodiment.

FIG. 18 is a cross-sectional view schematically illustrating a member arranging step according to an eighth embodiment.

### DESCRIPTION OF EMBODIMENTS

Embodiments according to the present disclosure will now be described in detail. A display device according to the present embodiments includes a plurality of light-emitting elements having a first face, arranged in units of subpixels constituting a pixel, and having at least one of a first electrically conducting electrode and a second electrically conducting electrode on the first face, a substrate having an electrode corresponding to the electrode on the first face of the plurality of light-emitting elements, an anisotropic conductive film providing an anisotropic electrically conductive connection between the electrode on the first face of the plurality of light-emitting elements and the electrode on the substrate, and a wavelength conversion member converting a wavelength of light from the light-emitting elements in units of subpixels.

The light-emitting elements may be in a lateral configuration, for example, in which a p-side first electrically conducting electrode and an n-side second electrically conducting electrode are located on the same side or may be in a vertical configuration, for example, in which a p-side first electrically conducting electrode and an n-side second electrically conducting electrode are on opposite sides of an interposing epitaxial layer.

In the case of the light-emitting elements being in a lateral configuration, anisotropic conductive connections may be made so that the first electrically conducting electrode and the second electrically conducting electrode are both connected with electrodes of the substrate, or an anisotropic conductive connection may be made so that only one of the first electrically conducting electrode and the second electrically conducting electrode is connected with an electrode of the substrate. In the case of making an anisotropic conductive connection so that only one of the first electrically conducting electrode and the second electrically conducting electrode is connected with an electrode of the substrate, it is preferable to form, for example, a pattern connecting an n-side electrode of adjacent light-emitting elements as, for example, a data line or address line of a matrix wiring and cover this pattern with an insulating film.

In the case of the light-emitting elements being in a vertical configuration, it is preferable to make an anisotropic conductive connection so that only one of the first electrically conducting electrode and second electrically conducting electrode is connected with an electrode of the substrate and form the other electrode as a transparent electrode, for example, as a pattern of a data line or address line of a matrix wiring.

The subpixels, for example, may be three in number with R (red), G (green), and B (blue) to constitute a pixel, four in number with RGB and W (white) or with RGB and Y (yellow) to constitute a pixel, or two in number with RG or GB to constitute a pixel. Furthermore, in order to prevent color mixing of adjacent subpixels, it is preferable to cover spaces between adjacent light-emitting elements with a black matrix (BM).

Furthermore, a method for manufacturing a display device according to the present embodiment includes, a connecting step of compression bonding a wafer on which a plurality of light-emitting elements are arranged in units of subpixels constituting a pixel, the plurality of light-emitting elements having at least one of a first electrically conducting electrode and a second electrically conducting electrode on a first face, to a substrate having an electrode corresponding to the electrode on the first face of the plurality of light-emitting elements via an anisotropic conductive adhesive providing an anisotropic conductive connection between the electrode on the first face of the plurality of light-emitting elements and the electrode on the substrate, and a member arranging step of arranging a wavelength conversion member converting a wavelength of light from the light-emitting elements in units of subpixels.

According to the present embodiment, by using an anisotropic conductive adhesive, a plurality of light-emitting elements can be batch-mounted in an arrangement in units of subpixels formed on a wafer to achieve improved brightness and resolution. Furthermore, by batch-mounting the light-emitting elements on the wafer, mounting times can be shortened and throughput as well as yield can be significantly improved.

As embodiments, examples using light-emitting elements in a lateral configuration with three-color RGB subpixels constituting one pixel are explained below.

### 1. First Embodiment

Display Device According to First Embodiment

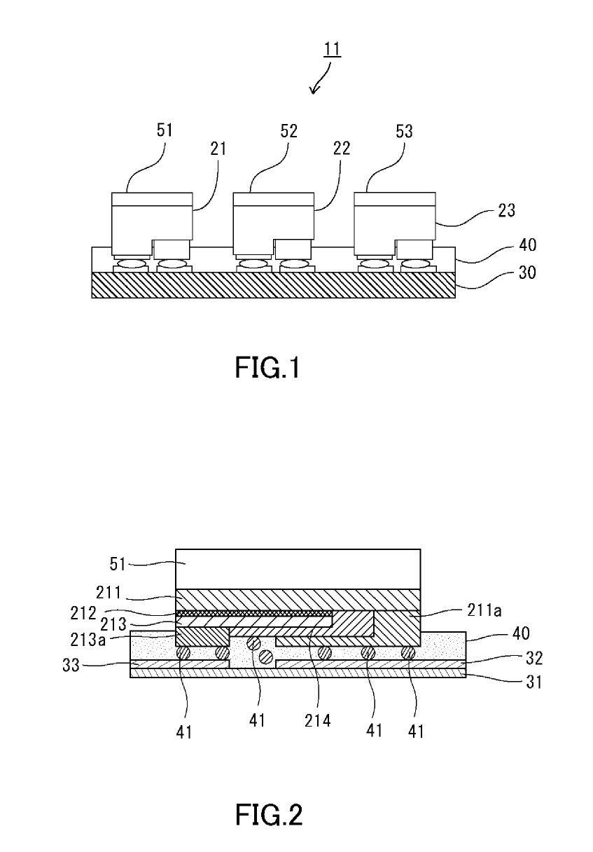

FIG. 1 is a cross-sectional view schematically illustrating a display device according to a first embodiment. A display device 11 according to the first embodiment has a wavelength conversion member which includes a phosphor layer converting light into red light, green light or blue light arrayed in units of subpixels above the plurality of light-emitting elements.

Thus, a display device 11 includes light-emitting elements 21, 22, and 23 arranged in units of subpixels constituting a pixel and having a first electrically conducting electrode and a second electrically conducting electrode on one face, a substrate 30 having electrodes corresponding to the first electrically conducting electrode and the second electrically conducting electrode, an anisotropic conductive film 40 providing an anisotropic conductive connection between the light-emitting elements 21, 22, and 23 and the substrate 30, and phosphor layers 51, 52, and 53 respectively converting light into red light, green light, and blue light arrayed in units of subpixels on the light-emitting elements 21, 22, and 23.

The light-emitting elements 21, 22, and 23 have a first electrically conducting electrode and a second electrically conducting electrode on one face and are known as flip-chip LEDs (Light Emitting Diodes). The light-emitting elements 21, 22, and 23 preferably emit ultraviolet to blue light and preferably have a peak wavelength of 200 to 500 nm. Size of the light-emitting elements 21, 22, and 23 can be selected in accordance with display panel size, the length of the long rectangular dimension being 0.5 mm or less, preferably 0.1 mm or less, and more preferably 0.01 mm or less. For example, in the case of employing 0.005×0.005 mm LEDs with nine LEDs per pixel at 3840×2160 pixels, by using a three inch or larger wafer, a display device with a screen size of 57.6×32.4 mm can be achieved.

For example, the light-emitting elements 21, 22, and 23 are arrayed on the substrate 30 in correspondence with each three-color RGB subpixel constituting a pixel to constitute an LED array. Examples of RGB subpixel arraying methods include striped arrays, mosaic arrays, and delta arrays, among others. A striped array arrangement has RGB arrayed in a vertical stripe shape and can achieve high resolution. Furthermore, a mosaic array arrangement has RGB arrayed with the same color along a diagonal and can create a more natural image than a striped arrangement. Moreover, a delta array arrangement has RGB arrayed in a triangle with each dot offset a half-pitch per field and can create a natural image display.

FIG. 2 is a cross-sectional view schematically illustrating an example of one mounted light-emitting element. The light-emitting element 21 has a first conductive cladding layer 211 made of, for example, n-GaN, an active layer 212 made of, for example, an InₓAl_{y}Ga_{1-x-y}N, and a second conductive cladding layer 213 made of, for example, p-GaN, in what is known as a double heterostructure. Moreover, the light-emitting element 21 has a first electrically conducting electrode 211a formed in a part of the first conductive cladding layer 211 and the second electrically conducting electrode 213a formed in a part of the second conductive cladding layer 213 by a passivation layer 214. Voltage applied across the first electrically conducting electrode 211a and the second electrically conducting electrode 213a concentrates carriers in an active layer 212 which recombine to generate light.

The substrate 30 is provided with a first conductive circuit pattern 32 and a second conductive circuit pattern 33 on a substrate material 31 and has electrodes corresponding to positions of the first electrically conducting electrode 211a and the second electrically conducting electrode 213a of the light-emitting element 21. Moreover, a circuit pattern, for example a data line or an address line of a matrix wiring, is formed on the substrate 30 that can turn the light-emitting elements corresponding to each subpixel ON/OFF.

Furthermore, the substrate 30 is preferably a transparent substrate. In the case of the substrate 30 being a transparent substrate, the substrate material 31 is preferably a transparent substrate material such as glass or PET (polyethylene terephthalate), and the first conductive circuit pattern 32 and the second conductive circuit pattern 33 as well as electrodes thereof are preferably a transparent conductive film such as ITO (Indium-Tin-Oxide), IZO (Indium-Zinc-Oxide), ZnO (Zinc-Oxide), or IGZO (Indium-Gallium-Zinc-Oxide). A transparent substrate as the substrate 30 allows the substrate 30 to serve as a display surface (light-emitting surface).

The anisotropic conductive film 40, is a cured product of an anisotropic conductive adhesive described below, trapping of conductive particles 41 between electrodes (electrodes 211a, 213a) of the light-emitting element 21 and terminals (electrodes) of the substrate 30 forms an anisotropic conductive connection between the light-emitting element 21 and the substrate 30. As the conductive particles 41, for example, resin-core metal-coated conductive particles as well as solder particles, among other metal particles, can be used and two or more types of metal particles may be used. Moreover, average particle diameter of the conductive particles 41 can be selected according to electrode size of the light-emitting elements 21, 22, and 23, and, in view of high resolution, is preferably 5 μm or less.

The phosphor layers 51, 52, and 53 convert light from the light-emitting elements 21, 22, and 23 into red light, green light, and blue light, respectively. As the phosphors of the phosphor layers 51, 52, and 53, nitrides or oxynitrides having high heat tolerance are preferably used. Moreover, as phosphors, it is preferable to use quantum dots which emit light in response to ultraviolet or blue light at a color corresponding to particle size of the quantum dots. It should be noted that, in the case of the light-emitting elements 21, 22, and 23 emitting blue light, a phosphor layer converting light into blue light may be omitted and this light transmitted.

In the case of the light-emitting elements 21, 22, and 23 being a blue LED, an R phosphor layer including a phosphor converting blue light into red light and a G phosphor layer including a phosphor converting blue light into green light are arrayed. As phosphors converting blue light into red light, for example, (Ca,Sr)₂Si₅N₈:Eu, (Ca,Sr)AlSiN₃:Eu, and CaSiN₂:Eu, among others, may be used. As phosphors converting blue light into green light, for example, ZnS:Cu, Al,SrGa₂S₄:Eu, (Ba,Sr)₂SiO₄:Eu, SrAl₂O₄:Eu, and (Si,Al)₆(O,N)₈:Eu, among others, may be used.

Furthermore, in the case of the light-emitting elements 21, 22, and 23 emitting near-ultraviolet light, an R phosphor layer including a phosphor converting near-ultraviolet light into red light, a G phosphor layer including a phosphor converting near-ultraviolet light into green light, and a B phosphor layer including a phosphor converting near-ultraviolet light into blue light are arrayed. As phosphors converting near-ultraviolet light into red light, for example, CaAlSiN₃:Eu, among others, may be used. As phosphors converting near-ultraviolet light into green light, for example, β-SiAlON:Eu, among others, may be used. As phosphors converting near-ultraviolet light into blue light, for example, (Sr,Ca,Ba,Mg)₁₀(PO₄)₆Cl₂:Eu, BaMgAl₁₀O₁₇:Eu, and (Sr,Ba)₃MgSi₂O₈:Eu, among others, may be used.

According to such a display device 11, because the phosphor layer can efficiently emit light from the light-emitting elements 21, 22, and 23, a high-brightness color screen can be achieved.

Method for Manufacturing Display Device According to First Embodiment

A method for manufacturing a display device according to the first embodiment includes, in a member arranging step, removing a wafer and arraying a phosphor layer converting light into red light, green light, or blue light in units of subpixels above a plurality of light-emitting elements.

Thus, a method for manufacturing a display device 11 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30 having electrodes respectively corresponding to the first electrically conducting electrode and the second electrically conducting electrode via an anisotropic conductive adhesive providing an anisotropic conductive connection between the plurality of light-emitting elements and the substrate, and a member arranging step of removing the wafer and arraying a phosphor layer converting light into red light, green light, or blue light on the plurality of light-emitting elements in units of subpixels. It should be noted that the same reference signs are given where structures are the same as in the display device 11 and further description is omitted.

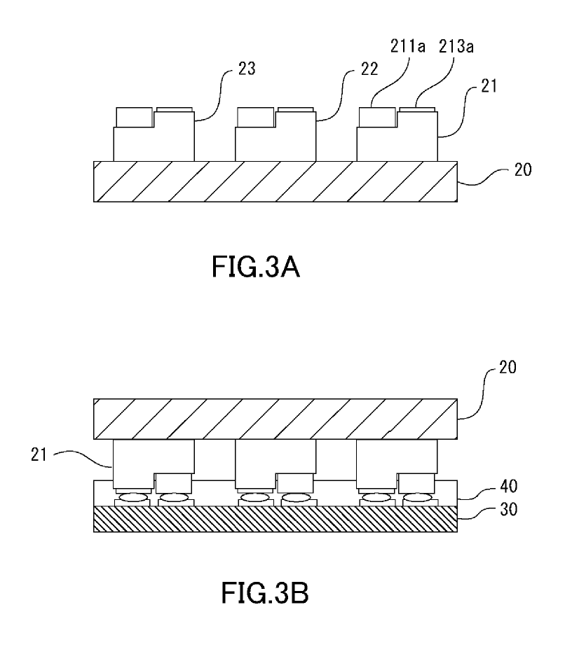

FIG. 3(A) is a cross-sectional view schematically illustrating a light-emitting element on a wafer, and FIG. 3(B) is a cross-sectional view schematically illustrating a step of connecting a light-emitting element and a substrate. As illustrated in FIG. 3(A), the light-emitting elements 21, 22, and 23 are formed on the wafer 20 in an RGB subpixel array. The wafer 20 is preferably a growth substrate such as a sapphire substrate, an SiC substrate, a GaN substrate, or an Si substrate, among others.

Next, an anisotropic conductive adhesive is applied or pasted onto the substrate 30 before aligning and mounting with the first electrically conducting electrodes and second electrically conducting electrodes of the light-emitting elements 21, 22, and 23 facing the anisotropic conductive adhesive and applying pressure from above the wafer 20. For example, in the case of using a thermosetting anisotropic conductive adhesive, thermocompression bonding conditions are, for example, preferably 150 to 260° C. for 10 to 300 seconds at a pressure of 10 to 60 MPa. The anisotropic conductive adhesive cures to form the anisotropic conductive film 40.

Furthermore, the wafer on which the plurality of light-emitting elements are formed may be aligned, mounted, and used to make anisotropic conductive connections multiple times. This enables manufacturing of large display devices.

The anisotropic conductive adhesive has conductive particles 41 dispersed in a binder (adhesive component), and forms such as paste or film, among other forms, may be selected as appropriate according to purpose.

Average particle diameter of the conductive particles can be selected according to size of electrodes of the light-emitting element and, in view of high resolution, is preferably 5 μm or less. As the conductive particles, metal-coated resin particles and solder particles are preferably used together.

The metal-coated resin particles are a resin particle such as of epoxy resin, phenol resin, acrylic resin, acrylonitrile/styrene (AS) resin, benzoguanamine resin, divinylbenzene resin, or styrene resin coated on the surface with a metal such as Au, Ni, or Zn. The metal-coated resin particles are easily crushed and deformed when pressed so that contact surface area with wiring patterns is increased and can compensate for variations in wiring pattern height.

The solder particles can be selected as appropriate in accordance with electrode material and connection conditions from, for example, as defined in JIS Z 3282-1999, Sn—Pb, Pb—Sn—Sb, Sn—Sb, Sn—Pb—Bi, Bi—Sn, Sn—Cu, Sn—Pb—Cu, Sn—In, Sn—Ag, Sn—Pb—Ag and Pb—Ag solder particles. In addition, shape of the solder particles can be selected as appropriate from granular shapes and flake shapes, among others. Furthermore, average particle diameter of the solder particles is preferably smaller than that of the conductive particles, and the average particle diameter of the solder particles is preferably 20% or more and less than 100% of the average particle diameter of the conductive particles. If the solder particles are too small in comparison with the conductive particles, the solder particles are not trapped between opposing electrodes when compressed and do not undergo metal bonding so that it is not possible to achieve excellent thermal dissipation and electrical properties. However, if the solder particles are too large in comparison with the conductive particles, the solder particles might cause leaks generated by shoulder touch in edge portions of, for example, an LED chip, which would cause poor product yields.

As the adhesive component, known thermosetting, ultraviolet setting, and combined heat/ultraviolet setting adhesive compositions used in conventional anisotropic conductive adhesives and anisotropic conductive films may be used. Epoxy adhesives and acrylic adhesives, among others, may be used in the adhesive composition, among these, an epoxy curing adhesive having a main component of a hydrogenated epoxy compound, alicyclic epoxy compound, heterocyclic epoxy compound, or similar compound can be preferably used. Among these, hydrogenated epoxy compounds such as hydrogenated bisphenol A epoxy resin having excellent light transmittance and rapid curing properties are preferably used. An example of a hydrogenated bisphenol A epoxy resin is trade name YX8000 available from Mitsubishi Chemical Corporation.

As a curing agent, aluminum chelate curing agents, acid anhydrides, imidazole compounds, and dicyans, among others, may be used. Among these, an aluminum chelate curing agent not prone to causing discoloration in cured products is preferable for use. As an aluminum chelate curing agent, Japanese Unexamined Patent Application Publication No. 2009-197206 describes, for example, holding an aluminum chelating agent and a silanol compound in a porous resin obtained by interfacially polymerizing a polyfunctional isocyanate compound and radical polymerizing divinylbenzene.

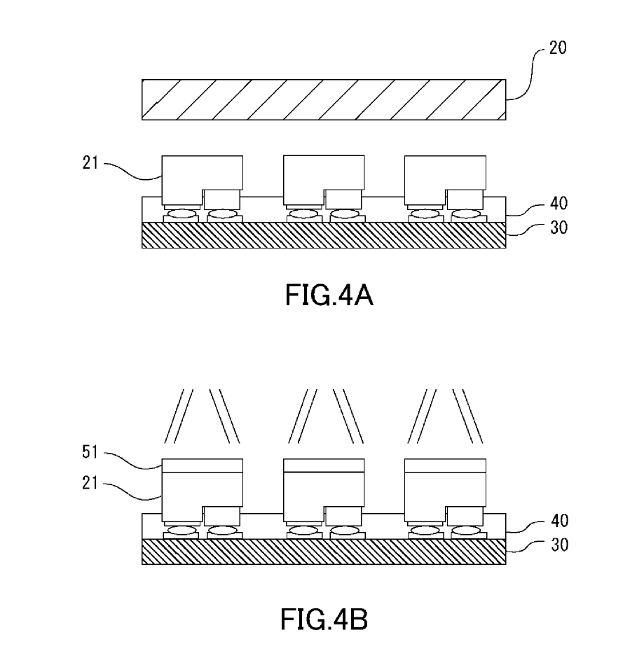

FIG. 4 is a cross-sectional view schematically illustrating a member arranging step of the first embodiment, FIG. 4(A) illustrates a step of removing the wafer, and FIG. 4(B) illustrates a step of forming a phosphor layer.

As illustrated in FIG. 4(A), in the member arranging step, the wafer 20 is lifted off and removed. A laser lift-off device is preferably used to lift off the wafer 20. By using the laser lift-off device, pulsed high-density UV laser light passing through the wafer 20 reaches the GaN layer and decomposes GaN into Ga and N₂ (nitrogen) across a depth of approximately 20 nm so that the wafer 20 can be separated without damaging LED structures.

Next, as illustrated in FIG. 4(B), a transparent resin containing a phosphor converting light into red light, green light, or blue light is coated on the plurality of light emitting elements 21, 22, and 23, that is, on the first conductive cladding layer 211, to form the phosphor layers 51, 52, and 53. As the transparent resin, an epoxy or silicone resin, among others, can be used. Moreover, ink-jet printing, among other methods, can be used to apply the transparent resin containing the phosphor.

According to such a method for manufacturing a display device 11, the light-emitting elements can be batch-mounted on the wafer 20, and by removing the wafer 20, light-loss otherwise caused by the wafer 20 can be improved. Furthermore, by forming the phosphor layers 51, 52, and 53 on the light-emitting elements 21, 22, and 23 arrayed in units of subpixels, a display device can be easily achieved.

### 2. Second Embodiment

Display Device According to Second Embodiment

FIG. 5 is a cross-sectional view schematically illustrating a display device according to a second embodiment. A display device 12 according to the second embodiment has a wafer 20 on a side of the plurality of light-emitting elements opposite to that on which the first electrically conducting electrode and second electrically conducting electrode are formed, and a wavelength conversion member having a phosphor layer converting light into red light, green light, and blue light arrayed in units of subpixels above the wafer 20.

Thus, a display device 12 includes a wafer 20, light-emitting elements 21, 22, and 23 arranged in units of subpixels constituting a pixel and having a first electrically conducting electrode and a second electrically conducting electrode on a side opposite the wafer 20, a substrate 30 having electrodes corresponding to the first electrically conducting electrodes and second electrically conducting electrodes, an anisotropic conductive film 40 providing an anisotropic conductive connection between the light-emitting elements 21, 22, and 23 and the substrate 30, and phosphor layers 51, 52, and 53, converting light into red light, green light, and blue light respectively, arrayed in units of subpixels on the wafer 20. It should be noted that the same reference signs are given where structures are the same as in the first embodiment and further description is omitted.

Such a display device 12, despite light-loss due to the wafer 20, is free of metal wiring of wire bonds above the display side, thus enabling a high-brightness color screen.

Method for Manufacturing Display Device According to Second Embodiment

In a method for manufacturing a display device according to the second embodiment, the member arranging step includes arraying a phosphor layer converting light into red light, green light, or blue light in units of subpixels above the wafer.

Thus, a method for manufacturing a display device 12 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30 having electrodes respectively corresponding to the first electrically conducting electrode and the second electrically conducting electrode via an anisotropic conductive adhesive providing an anisotropic conductive connection between the plurality of light-emitting elements and the substrate, and a member arranging step of arraying a phosphor layer converting light into red light, green light, or blue light in units of subpixels on the wafer 20. It should be noted that the same reference signs are given where structures are the same as in the display device 12, and further description is omitted. Moreover, because the connecting step is the same as in the first embodiment, further description is omitted.

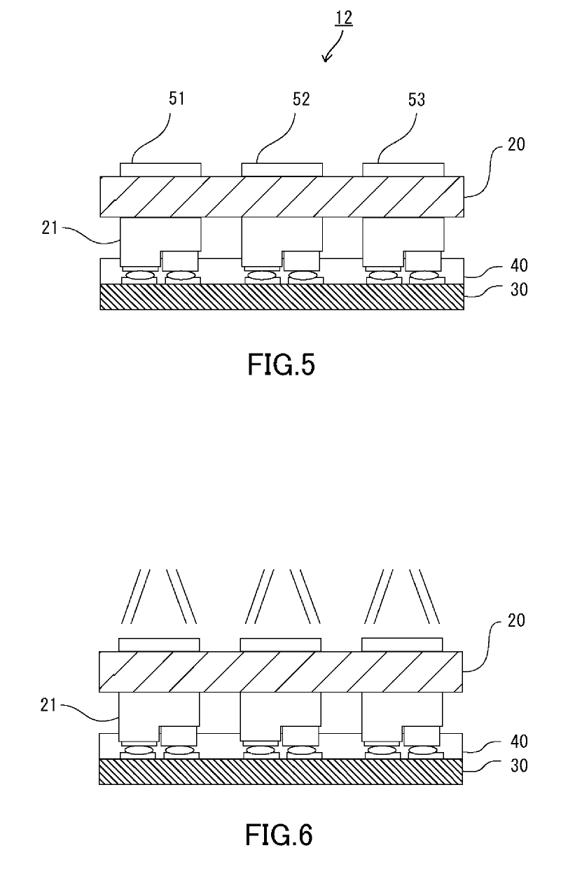

FIG. 6 is a cross-sectional view schematically illustrating the member arranging step according to the second embodiment. As illustrated in FIG. 6, the member arranging step includes coating a transparent resin containing a phosphor converting light into red light, green light, or blue light on the wafer 20 to form the phosphor layers 51, 52, and 53. As the transparent resin, an epoxy or silicone resin, among others, can be used. Moreover, ink-jet printing, among other methods, can be used to apply the transparent resin containing the phosphor.

Such a method for manufacturing a display device 12 allows omission of a process for removing the wafer 20. Moreover, after the connection step, simply forming the phosphor layers 51, 52, and 53 in units of subpixels on the wafer 20 can easily achieve a display device.

### 3. Third Embodiment

Display Device According to Third Embodiment

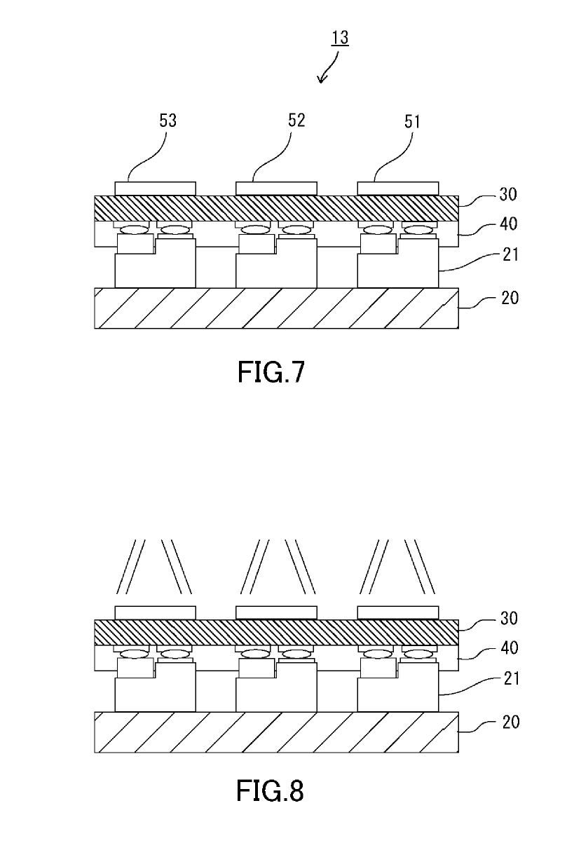

FIG. 7 is a cross-sectional view schematically illustrating a display device according to a third embodiment. In a display device 13 according to the third embodiment, the substrate 30 is a transparent substrate, and a wavelength conversion member having a phosphor layer converting light into red light, green light, or blue light is arrayed in units of subpixels on the substrate 30.

Thus, a display device 13 includes a wafer 20, light-emitting elements 21, 22, and 23 arranged in units of subpixels constituting a pixel, and having a first electrically conducting electrode and a second electrically conducting electrode on a side opposite the wafer 20, a substrate 30 which is a transparent substrate and has electrodes corresponding to the first electrically conducting electrode and the second electrically conducting electrode, an anisotropic conductive film 40 providing an anisotropic conductive connection between the light-emitting elements 21, 22, and 23 and the substrate 30, and phosphor layers 51, 52, and 53, converting light into red light, green light, and blue light respectively, arrayed in units of subpixels on the substrate 30. It should be noted that the same reference signs are given where structures are the same as in the first embodiment, and further description is omitted.

Such a display device 13, despite light-loss due to connecting portions, is free of metal wiring of wire bonds above the display side, which enables a high-brightness color screen.

Method for Manufacturing Display Device According to Third Embodiment

In a method for manufacturing a display device according to the third embodiment, the substrate is a transparent substrate and the member arranging step includes arraying a phosphor layer converting light into red light, green light, or blue light in units of subpixels above the transparent substrate.

Thus, a method for manufacturing a display device 13 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30, which is a transparent substrate having electrodes respectively corresponding to the first electrically conducting electrode and the second electrically conducting electrode via an anisotropic conductive adhesive providing an anisotropic conductive connection between the plurality of light-emitting elements and the substrate, and a member arranging step of arraying a phosphor layer converting light into red light, green light, or blue light in units of subpixels on the substrate 30. It should be noted that the same reference signs are given where structures are the same as in the display device 13, and further description is omitted. Moreover, because the connecting step is the same as in the first embodiment, further description is omitted.

FIG. 8 is a cross-sectional view illustrating the member arranging step of the third embodiment. As illustrated in FIG. 8, the member arranging step includes coating a transparent resin containing a phosphor converting light into red light, green light, or blue light on the substrate 30 to form the phosphor layers 51, 52, and 53. As the transparent resin, an epoxy or silicone resin, among others, can be used. Moreover, ink-jet printing, among other methods, can be used to apply the transparent resin containing the phosphor.

Such a method for manufacturing a display device 13 allows omission of a process for removing a wafer. Moreover, after the connection step, simply forming the phosphor layers 51, 52, and 53 in units of subpixels on the substrate 30 can easily achieve a display device.

### 4. Fourth Embodiment

Display Device According to Fourth Embodiment

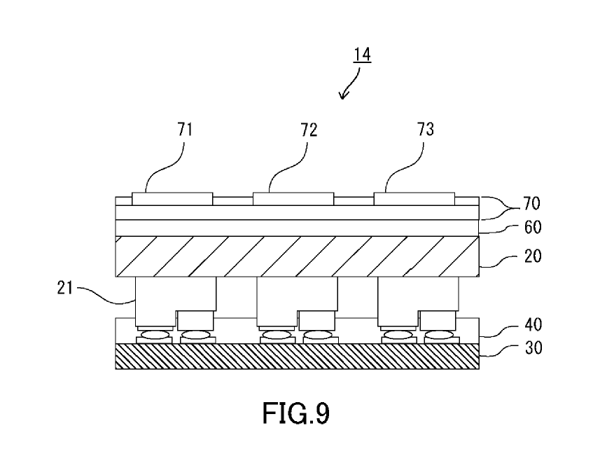

FIG. 9 is a cross-sectional view schematically illustrating a display device according to a fourth embodiment. A display device 14 according to the fourth embodiment includes a plurality of light-emitting elements having a wafer 20 on a side opposite a side on which the first electrically conducting electrode and second electrically conducting electrode are formed, and a wavelength conversion member arranged on the wafer 20 including a phosphor layer 60 converting light from the light-emitting elements 21, 22, and 23 into white light, and a color filter 70 converting white light from the phosphor layer 60 into red light, green light, or blue light in units of subpixels.

Thus, the display device 14 includes a wafer 20, light-emitting elements 21, 22, and 23 arranged in units of subpixels constituting a pixel and having a first electrically conducting electrode and a second electrically conducting electrode on a side opposite the wafer 20, a substrate 30 having electrodes corresponding to the first electrically conducting electrode and second electrically conducting electrode, an anisotropic conductive film 40 providing an anisotropic conductive connection between the light-emitting elements 21, 22, and 23 and the substrate 30, a phosphor layer 60 formed on the wafer 20 and converting light from the light-emitting elements 21, 22, and 23 into white light, and a color filter 70 arranged in units of subpixels and converting white light from the phosphor layer 60 into red light, green light, or blue light. It should be noted that the same reference signs are given where structures are the same as in the first embodiment and further description is omitted.

In the phosphor layer 60, light emitted from the light-emitting elements 21, 22, and 23 and light emitted from the phosphor layer 60 are mixed to obtain white light. For example, in the case of the light-emitting elements 21, 22, and 23 being blue LEDs, as the phosphor of the phosphor layer 60 Y₃Al₅O₁₂:Ce (YAG), CaGa₂S₄:Eu, and SrSiO₄:Eu, among others, may be used.

Moreover, for example, in the case of the light-emitting elements 21, 22, and 23 being near-ultraviolet emitting LEDs, two varieties of phosphors can be used to convert near-ultraviolet light into yellow light and blue light. As a phosphor converting near-ultraviolet light into yellow light, for example, Ca-α-SiAlON:Eu can be used. As a phosphor converting near-ultraviolet light into blue light, for example, (Sr,Ca,Ba,Mg)₁₀(PO₄)₆Cl₂:Eu, BaMgAl₁₀O₁₇:Eu, (Sr,Ba)₃MgSi₂O₈:Eu, among others, may be used.

The color filter 70 has colored layers 71, 72, and 73 transmitting red, green and blue light corresponding with the light-emitting elements 21, 22, and 23 arranged in units of subpixels. As a substrate material, a transparent material such as glass or PET may be used. As the colored layers 71, 72, and 73 dyed or pigmented layers, among others, may be used. Further, it is preferable to arrange a black matrix (BM) on the substrate on the substrate material to prevent color mixing.

Such a display device 14, despite light-loss due to the wafer 20, is free of metal wiring of wire bonds above the display side, thus enabling a high-brightness color screen. It should be noted that the wafer 20 may be lifted off and the phosphor layer 60 provided on the light-emitting elements 21, 22, and 23 to efficiently transmit light from the light-emitting elements 21, 22, and 23 to the phosphor layer 60.

Method for Manufacturing Display Device According to Fourth Embodiment

In a method for manufacturing a display device according to the fourth embodiment, the member arranging step includes forming a phosphor layer converting light from the light-emitting elements into white light above the wafer, and arranging a color filter converting white light into red light, green light, or blue light in units of subpixels above the phosphor layer.

Thus, a method for manufacturing a display device 14 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30 having electrodes respectively corresponding to the first electrically conducting electrode and the second electrically conducting electrode via an anisotropic conductive adhesive providing an anisotropic conductive connection between the plurality of light-emitting elements and the substrate, and a member arranging step which includes forming a phosphor layer 60 converting light from the light-emitting elements into white light on the wafer 20 and arranging a color filter 70 converting white light into red light, green light, or blue light in units of subpixels on the phosphor layer 60. It should be noted that the same reference signs are given where structures are the same as in the display device 14, and further description is omitted. Moreover, because the connecting step is the same as in the first embodiment, further description is omitted.

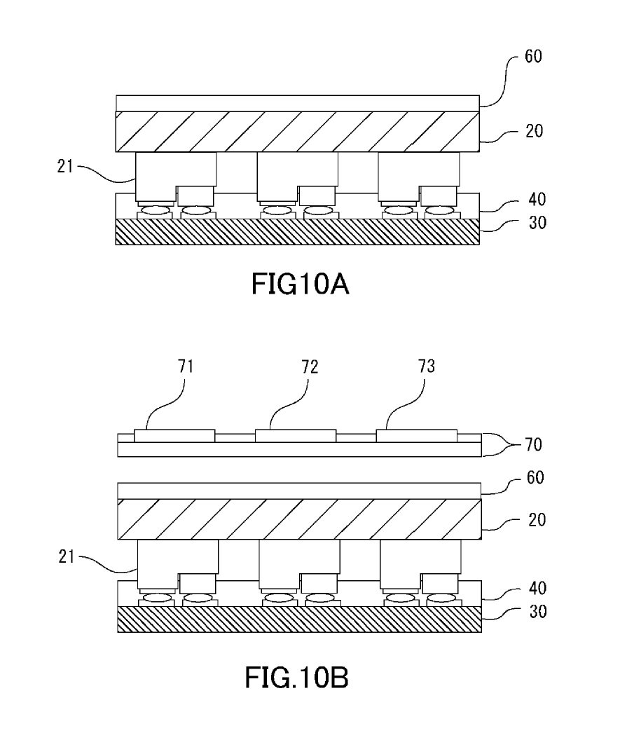

FIG. 10 is a cross-sectional view schematically illustrating a member arranging step according to the fourth embodiment, FIG. 10(A) illustrates step of forming a phosphor layer, and FIG. 10(B) illustrates a step of arranging a color filter.

As illustrated in FIG. 10(A), in the member arranging step, first, a transparent resin containing a phosphor converting light from the light-emitting elements into white light is applied on the wafer 20 to form a phosphor layer 60. As the transparent resin, an epoxy or silicone resin, among others, can be used. Moreover, methods such as spin-coating and ink-jet printing can be used to apply the transparent resin containing the phosphor.

Next, as illustrated in FIG. 10(B), a color filter 70 is applied on the phosphor layer 60. When applying the color filter 70, the colored layers 71, 72, and 73 are arranged to correspond to the light-emitting elements 21, 22, and 23 arranged in units of subpixels.

Such a method for manufacturing a display device 14 allows omission of a process for removing a wafer 20. Furthermore, simply forming the phosphor layer 60 on the wafer 20 and applying the color filter 70 can easily achieve a display device. It should be noted that the wafer 20 may be lifted off, and a phosphor sheet converting light into white light and a color filter may be applied to the light-emitting elements 21, 22, and 23 so that a phosphor layer 60 is provided on the light-emitting elements 21, 22, and 23.

### 5. Fifth Embodiment

Display Device According to Fifth Embodiment

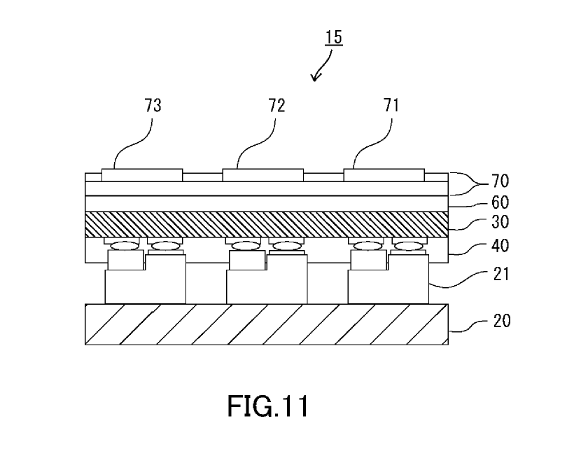

FIG. 11 is a cross-sectional view schematically illustrating a display device according to a fifth embodiment. A display device 15 according to the fifth embodiment includes a substrate 30 that is a transparent substrate, and a wavelength conversion member arranged above the substrate 30, the wavelength conversion member including a phosphor layer 60 converting light from the light-emitting elements 21, 22, and 23 into white light as well as a color filter 70 converting white light from the phosphor layer 60 into red light, green light, or blue light in units of subpixels.

Thus, a display device 15 includes a wafer 20, light-emitting elements 21, 22, and 23 arranged in units of subpixels constituting a pixel and having a first electrically conducting electrode and a second electrically conducting electrode on a side opposite the wafer 20, a substrate 30 which is a transparent substrate and has electrodes corresponding to the first electrically conducting electrode and the second electrically conducting electrode, an anisotropic conductive film 40 providing an anisotropic conductive connection between the light-emitting elements 21, 22, and 23 and the substrate 30, a phosphor layer 60 converting light from the light-emitting elements 21, 22, and 23 formed on the substrate 30 into white light, and a color filter 70 converting white light from the phosphor layer 60 into red light, green light, or blue light in units of subpixels. It should be noted that the same reference signs are given where structures are the same as in the fourth embodiment and further description is omitted.

Such a display device 15, despite light-loss due to connecting portions, is free of metal wiring of wire bonds above the display side, thus enabling a high-brightness color screen.

Method for Manufacturing Display Device According to Fifth Embodiment

In a method for manufacturing a display device according to the fifth embodiment, the substrate is a transparent substrate, and the member arranging step includes forming a phosphor layer converting white light from the light-emitting elements above the substrate, and arranging a color filter converting white light into red light, green light, or blue light in units of subpixels above the phosphor layer.

Thus, a method for manufacturing a display device 15 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30, which is a transparent substrate, having electrodes respectively corresponding to the first electrically conducting electrode and the second electrically conducting electrode via an anisotropic conductive adhesive providing an anisotropic conductive connection between the plurality of light-emitting elements and the substrate, and a member arranging step of forming a phosphor layer 60 converting white light from the light-emitting elements on the substrate 30, and arranging a color filter 70 converting white light into red light, green light, or blue light on the phosphor layer 60 in units of subpixels. It should be noted that the same reference signs are given where structures are the same as in the display device 15, and further description is omitted. Moreover, because the connecting step is the same as in the first embodiment, further description is omitted.

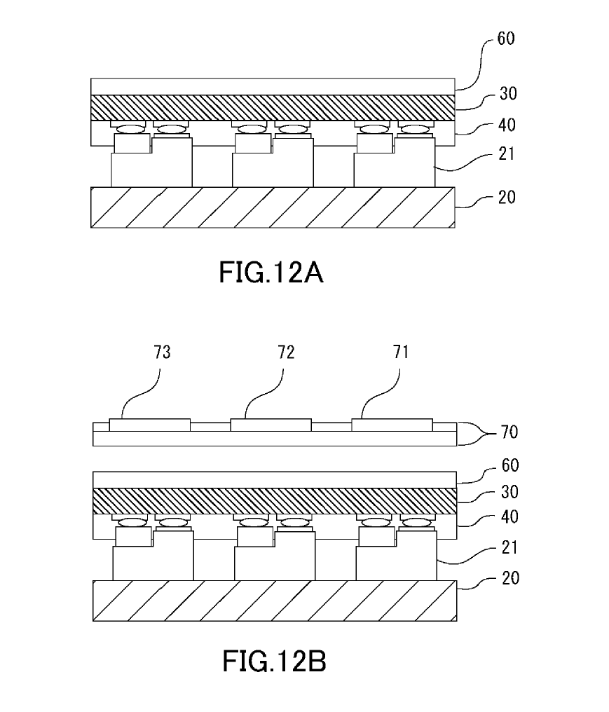

FIG. 12 is a cross-sectional view schematically illustrating a member arranging step in a fifth embodiment, FIG. 12(A) illustrates a step of forming a phosphor layer, and FIG. 12(B) illustrates a step of arranging a color filter.

As illustrated in FIG. 12 (A), in the member arranging step, first, a transparent resin containing a phosphor converting light from the light-emitting elements into white light is applied on the substrate 30 to form a phosphor layer 60. As the transparent resin, an epoxy or silicone resin, among others, can be used. Moreover, ink-jet printing, among other methods, can be used to apply the transparent resin containing the phosphor.

Next, as illustrated in FIG. 12 (B), a color filter 70 is applied on the phosphor layer 60. When pasting the color filter 70, the colored layers 71, 72, and 73 are arranged to correspond to the light-emitting elements 21, 22, and 23 arranged in units of subpixels.

Such a method for manufacturing a display device 15 allows omission of a process for removing a wafer 20. Moreover, after the connection step, simply forming the phosphor layer 60 on the substrate 30 and applying the color filter 70 can easily achieve a display device.

### 6. Sixth Embodiment

Display Device According to Sixth Embodiment

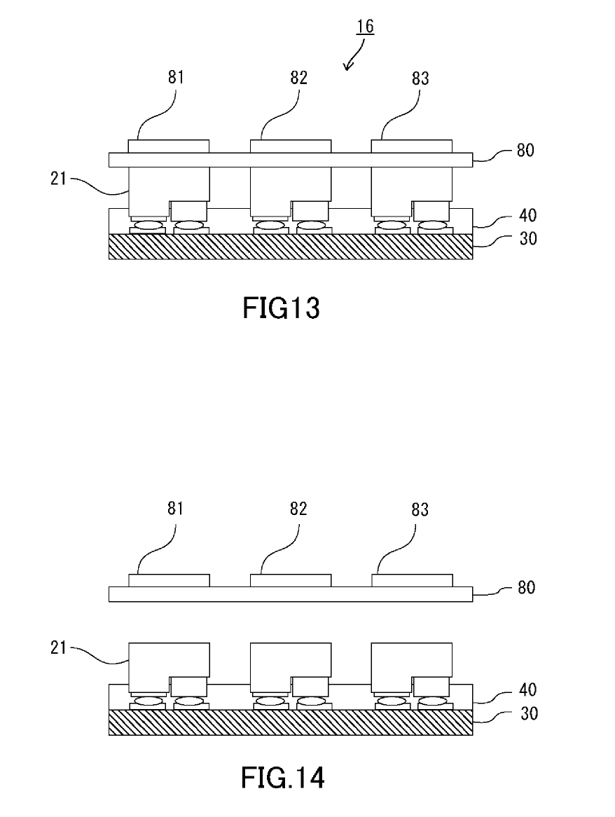

FIG. 13 is a cross-sectional view schematically illustrating a display device according to a sixth embodiment. A display device 16 according to the sixth embodiment includes a wavelength conversion member including a phosphor sheet formed of a phosphor layer converting light into red light, green light, or blue light arrayed in units of subpixels, the phosphor sheet being arranged above the plurality of light-emitting elements.

Thus, a display device 16 includes light-emitting elements 21, 22, and 23 arranged in units of subpixels constituting a pixel and having a first electrically conducting electrode and a second electrically conducting electrode on one side, a substrate 30 having electrodes corresponding to the first electrically conducting electrodes and second electrically conducting electrodes, an anisotropic conductive film 40 providing an anisotropic conductive connection between the light-emitting elements 21, 22, and 23 and the substrate 30, and a phosphor sheet 80 arranged on the light-emitting elements 21, 22, and 23 and formed of phosphor layers 81, 82, and 83 converting light into red light, green light, or blue light arrayed in units of subpixels. It should be noted that the same reference signs are given where structures are the same as in the first embodiment and further description is omitted.

The phosphor sheet 80 has the phosphor layers 81, 82, and 83 converting light into red light, green light, or blue light and arranged to correspond with the light-emitting elements 21, 22, and 23 arranged in units of subpixels. As a substrate material, a transparent material such as glass or PET may be used. As the phosphor layers 81, 82, and 83, the same phosphors as those of the phosphor layers 51, 52, and 53 described in the first embodiment may be used.

According to such a display device 16, the phosphor layer can efficiently emit light from the light-emitting elements 21, 22, and 23, which enables a high-brightness color screen.

Method for Manufacturing Display Device According to Sixth Embodiment

In a method for manufacturing a display device according to the sixth embodiment, the member arranging step includes removing the wafer and arranging a phosphor sheet made of a phosphor layer, converting light into red light, green light, and blue light and arrayed in units of subpixels, above a plurality of light-emitting elements.

Thus, a method for manufacturing a display device 16 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30 having electrodes respectively corresponding to the first electrically conducting electrode and the second electrically conducting electrode via an anisotropic conductive adhesive providing an anisotropic conductive connection between the plurality of light-emitting elements and the substrate, and a member arranging step of removing the wafer and arranging a phosphor sheet made of a phosphor layer converting light into red light, green light, or blue light arrayed in units of subpixels on a plurality of light-emitting elements. It should be noted that the same reference signs are given where structures are the same as in the display device 16, and further description is omitted. Moreover, because the connecting step is the same as in the first embodiment, further description is omitted.

FIG. 14 is a cross-sectional view schematically illustrating a member arranging step according to the sixth embodiment. In the member arranging step, the wafer 20 is lifted off and removed. A laser lift-off device is preferably used to lift off the wafer 20 as described in the first embodiment.

Next, as illustrated in FIG. 14, a phosphor sheet 80 made from phosphor layers 81, 82, and 83 converting light into red light, green light, and blue light arrayed in units of subpixels is applied on the plurality of light-emitting elements 21, 22 and 23, that is, on the first conductive cladding layer 211. When applying the phosphor sheet 80, the colored layers 81, 82, and 83 are arranged to correspond with the light-emitting elements 21, 22, and 23 arranged in units of subpixels.

According to such a method for manufacturing a display device 16, after the connecting step, simply lifting off the wafer 20 and applying the phosphor sheet 80 on the light-emitting elements 21, 22, and 23 can easily achieve a display device.

### 7. Seventh Embodiment

Display Device According to Seventh Embodiment

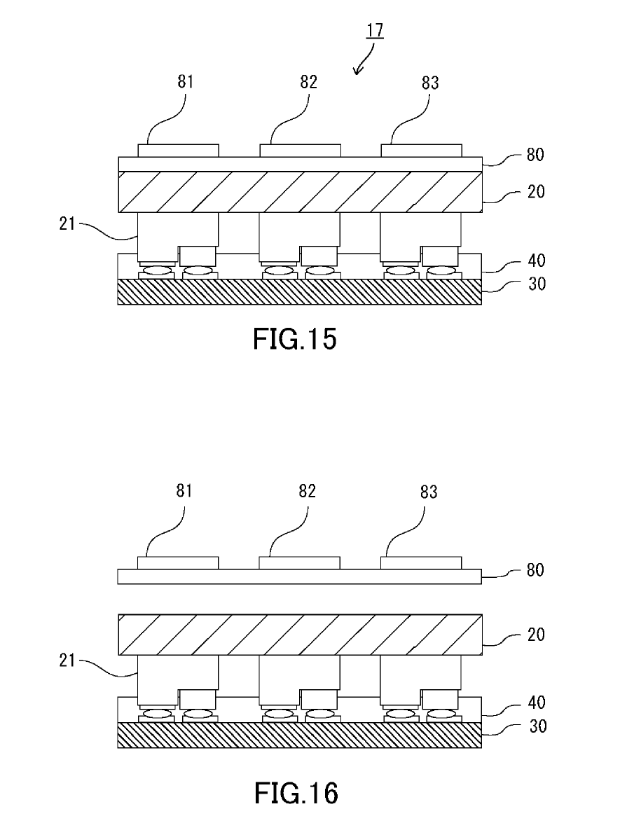

FIG. 15 is a cross-sectional view schematically illustrating a display device according to a seventh embodiment. A display device 17 according to the seventh embodiment includes a plurality of light-emitting elements having a wafer 20 on a side opposite a side on which a first electrically conducting electrode and second electrically conducting electrode are formed, and a wavelength conversion member is arranged on the wafer 20 including a phosphor layer converting light into red light, green light, or blue light arrayed in units of subpixels.

Thus, a display device 17 includes a wafer 20, light-emitting elements 21, 22, and 23 arranged in units of subpixels constituting a pixel, having a first electrically conducting electrode and a second electrically conducting electrode on a side opposite the wafer 20, a substrate 30 having electrodes corresponding to the first electrically conducting electrodes and second electrically conducting electrodes, an anisotropic conductive film 40 providing an anisotropic conductive connection between the light-emitting elements 21, 22, and 23 and the substrate 30, and a phosphor sheet 80 arranged on the wafer 20, the phosphor sheet being formed of phosphor layers 81, 82, and 83 converting light into red light, green light, or blue light arrayed in units of subpixels. It should be noted that the same reference signs are given where structures are the same as in the sixth embodiment and further description is omitted.

Such a display device 17, despite light-loss due to the wafer 20, is free of metal wiring of wire bonds above the display side, thus enabling a high-brightness color screen.

Method for Manufacturing Display Device According to Seventh Embodiment

In a method for manufacturing a display device according to the seventh embodiment, the member arranging step includes arranging a phosphor sheet above a wafer, the phosphor sheet being formed of a phosphor layer converting light into red light, green light, and blue light and arrayed in units of subpixels.

Thus, a method for manufacturing a display device 17 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30 having electrodes respectively corresponding to the first electrically conducting electrode and the second electrically conducting electrode via an anisotropic conductive adhesive providing an anisotropic conductive connection between the plurality of light-emitting elements and the substrate, and a member arranging step of arranging a phosphor sheet 80 on the wafer 20, the phosphor sheet 80 being formed of a phosphor layer converting light into red light, green light, or blue light and arrayed in units of subpixels. It should be noted that the same reference signs are given where structures are the same as in the display device 17, and further description is omitted. Moreover, because the connecting step is the same as in the first embodiment, further description is omitted.

FIG. 16 is a cross-sectional view schematically illustrating the member arranging step according to the seventh embodiment. As illustrated in FIG. 16, the member arranging step includes arranging a phosphor sheet 80 formed of phosphor layers 81, 82, and 83, converting light into red light, green light, or blue light and arrayed in units of subpixels, on the wafer 20. When applying the phosphor sheet 80, the phosphor layers 81, 82, and 83 are arranged to correspond with the light-emitting elements 21, 22, and 23 which are arranged in units of subpixels.

Such a method for manufacturing a display device 17 allows omission of a process for removing the wafer 20. Moreover, after the connecting step, simply applying the phosphor sheet 80 onto the light-emitting elements 21, 22, and 23 can easily achieve a display device.

### 8. Eighth Embodiment

Display Device According to Eighth Embodiment

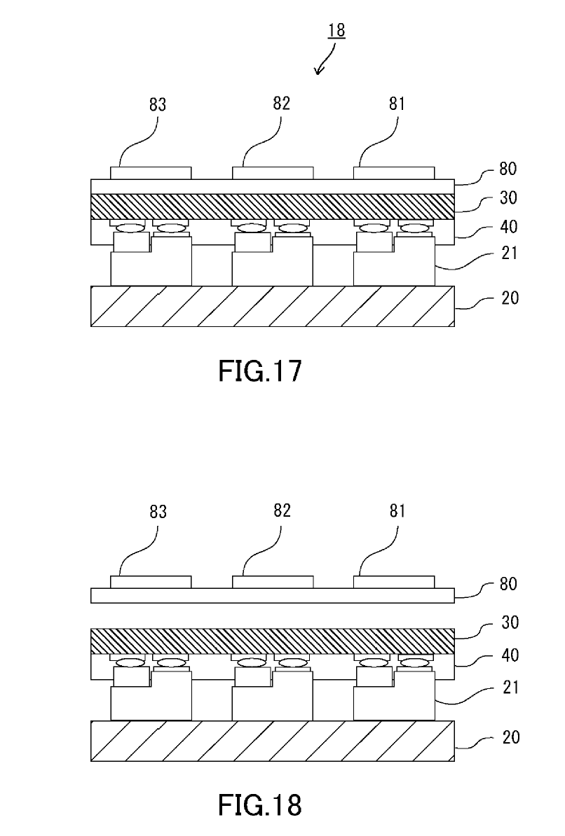

FIG. 17 is a cross-sectional view schematically illustrating a display device according to an eighth embodiment. In a method for manufacturing a display device 18 according to the eighth embodiment, the substrate 30 is a transparent substrate, and a wavelength conversion member is arranged above the substrate 30, the wavelength conversion member having a phosphor sheet formed of phosphor layers converting light into red light, green light, or blue light and arrayed in units of subpixels.

Thus, a display device 18 includes a wafer 20, light-emitting elements 21, 22, and 23 arranged in units of subpixels constituting a pixel and having a first electrically conducting electrode and a second electrically conducting electrode on a side opposite the wafer 20, a substrate 30 which is a transparent substrate and has electrodes corresponding to the first electrically conducting electrode and second electrically conducting electrode, an anisotropic conductive film 40 providing an anisotropic conductive connection between the light-emitting elements 21, 22, and 23 and the substrate 30, and a phosphor sheet 80 formed of phosphor layers 81, 82, and 83, converting light into red light, green light, or blue light and arrayed in units of subpixels, arranged on the substrate 30. It should be noted that the same reference signs are given where structures are the same as in the sixth embodiment and further description is omitted.

Such a display device 18, despite light-loss due to connecting portions, is free of metal wiring of wire bonds above the display side, thus enabling a high-brightness color screen.

Method for Manufacturing Display Device According to Eighth Embodiment

In a method for manufacturing a display device according to the eighth embodiment, the substrate is a transparent substrate, and the member arranging step includes arranging a phosphor sheet formed of phosphor layers, converting light into red light, green light, or blue light and arrayed in units of subpixels, above the substrate.

Thus, a method for manufacturing a display device 18 includes a connecting step of compression bonding a wafer 20 on which a plurality of light-emitting elements are arranged in units of subpixels constituting a pixel, the plurality of light-emitting elements having a first electrically conducting electrode and a second electrically conducting electrode on one face, to a substrate 30 which is a transparent substrate and which has electrodes respectively corresponding to the first electrically conducting electrode and the second electrically conducting electrode via an anisotropic conductive adhesive providing an anisotropic conductive connection between the plurality of light-emitting elements and the substrate, and a member arranging step of arranging a phosphor sheet 80 formed of phosphor layers 81, 82, and 83, converting light into red light, green light, or blue light and arrayed in units of subpixels, on the substrate 30. It should be noted that the same reference signs are given where structures are the same as in the display device 18 and further description is omitted. Moreover, because the connecting step is the same as in the first embodiment, further description is omitted.

FIG. 18 is a cross-sectional view schematically illustrating a member arranging step according to the eighth embodiment. As illustrated in FIG. 18, a member arranging step includes applying a phosphor sheet 80 formed of phosphor layers 81, 82, and 83, converting light into red light, green light, or blue light and arrayed in units of subpixels, on the substrate 30. When applying the phosphor sheet 80, the phosphor layers 81, 82, and 83 are arranged to correspond with the light-emitting elements 21, 22, and 23 which are arranged in units of subpixels.

Such a method for manufacturing a display device 18 allows omission of a process for removing a wafer 20. Moreover, after the connecting step, simply applying the phosphor sheet 80 to the substrate 30 can easily achieve a display device.

### 9. Ninth Embodiment

Light-Emitting Device

A light-emitting device according to this embodiment includes a plurality of light-emitting elements having a first face, arranged in an array formed on a wafer, and having at least one of a first electrically conducting electrode and a second electrically conducting electrode on a first face, a substrate having an electrode corresponding to the electrode on the first face of the plurality of light-emitting elements, and an anisotropic conductive film providing an anisotropic conductive connection between the electrode on the first face of the plurality of light-emitting elements and the electrode of the substrate.

Thus, a light-emitting device in the embodiment described above has a plurality of light-emitting elements arrayed in an LED array. Because such a light-emitting device has increased fineness, a high-brightness light-emitting surface can be achieved.

Method for Manufacturing Light-Emitting Device

A method for manufacturing a light-emitting device according to the present embodiment includes compression bonding a wafer on which a plurality of light-emitting elements having a first face are arrayed, the plurality of light-emitting elements having at least one of a first electrically conducting electrode and a second electrically conducting electrode on the first face, to a substrate having an electrode corresponding to the electrode on the first face of the plurality of light-emitting elements via an anisotropic conductive adhesive providing an anisotropic conductive connection between the electrode on the first face of the plurality of light-emitting elements and the electrode of the substrate.

Thus, a method for manufacturing a light-emitting device according to the embodiment described above includes a connecting step using a wafer on which a plurality of light-emitting elements having at least one of a first electrically conducting electrode and second electrically conducting electrode on a first face are arrayed. According to such a method for manufacturing a light-emitting device, simply using an anisotropic conductive adhesive can easily achieve a high-brightness LED array.

### REFERENCE SIGNS LIST

11 display device, 21, 22, 23 light-emitting elements, 30 substrate, 31 substrate material, 32 first conductive circuit pattern, 33 second conductive circuit pattern, 40 anisotropic conductive film, 41 conductive particles, 51, 52, 53 phosphor layers, 60 phosphor layer, 70 color filter, 71, 72, 73 colored layers, 80 phosphor layer sheet, 81, 82, 83 phosphor layers, 211 first conductive cladding layer, 211a first electrically conducting electrode, 212 active layer, 213 second conductive cladding layer, 213a second electrically conducting electrode, 214 passivation layer

1. A display device comprising:
a plurality of light-emitting elements having a first face, arranged in units of subpixels constituting a pixel, and having at least one of a first electrically conducting electrode and a second electrically conducting electrode on the first face;
a substrate having an electrode corresponding to the electrode on the first face of the plurality of light-emitting elements;
an anisotropic conductive film providing an anisotropic conductive connection between the electrode on the first face of the plurality of light-emitting elements and the electrode of the substrate; and
a wavelength conversion member converting a wavelength of light from the light-emitting elements in units of subpixels.

2. The display device according to claim 1, wherein the plurality of light-emitting elements has a wafer on a side opposite to the first face, and
wherein the wavelength conversion member is arranged on the wafer.

3. The display device according to claim 1, wherein the substrate is a transparent substrate, and
wherein the wavelength conversion member is arranged on the transparent substrate.

4. The display device according to claim 1, wherein the wavelength conversion member includes a phosphor layer converting light into red light, green light, or blue light arrayed in units of subpixels on the plurality of light-emitting elements.

5. The display device according to claim 2, wherein the wavelength conversion member includes a phosphor layer converting light into red light, green light, or blue light arrayed in units of subpixels.

6. The display device according to claim 2, wherein the wavelength conversion member includes a phosphor layer converting light from the light-emitting elements into white light and includes a color filter converting white light from the phosphor layer into red light, green light, or blue light.

7. The display device according to claim 1, wherein the wavelength conversion member includes a phosphor sheet formed of a phosphor layer converting light into red light, green light, or blue light arrayed in units of subpixels, and
wherein the phosphor sheet is arranged on the plurality of light-emitting elements.

8. The display device according to claim 2, wherein the wavelength conversion member includes a phosphor sheet having a phosphor layer converting light into red light, green light, or blue light arrayed in units of subpixels.

9. A method for manufacturing a display device comprising:
a connecting step of compression bonding a wafer on which a plurality of light-emitting elements having a first face are arranged in units of subpixels constituting a pixel, the plurality of light-emitting elements having at least one of a first electrically conducting electrode and a second electrically conducting electrode on the first face, to a substrate having an electrode corresponding to the electrode on the first face of the plurality of light-emitting elements via an anisotropic conductive adhesive providing an anisotropic conductive connection between the electrode on the first face of the plurality of light-emitting elements and the electrode of the substrate; and
a member arranging step of arranging a wavelength conversion member converting a wavelength of light from the light-emitting elements in units of subpixels.

10. The method for manufacturing a display device according to claim 9, wherein the member arranging step includes removing the wafer and arraying a phosphor layer converting light into red light, green light, or blue light on the plurality of light-emitting elements in units of subpixels.

11. The method for manufacturing a display device according to claim 9, wherein the member arranging step includes arraying a phosphor layer converting light into red light, green light, or blue light on the wafer in units of subpixels.

12. The method for manufacturing a display device according to claim 9, wherein the substrate is a transparent substrate, and
wherein the member arranging step includes arranging a phosphor layer converting light into red light, green light, or blue light on the transparent substrate in units of subpixels.

13. The method for manufacturing a display device according to claim 9,
wherein the member arranging step includes forming a phosphor layer converting light from the light-emitting elements into white light on the wafer and arranging a color filter converting white light into red light, green light, or blue light in units of subpixels on the phosphor layer.

14. The method for manufacturing a display device according to claim 9, wherein the substrate is a transparent substrate and,
wherein the member arranging step includes forming a phosphor layer converting light from the light-emitting elements into white light on the transparent substrate and arranging a color filter converting white light into red light, green light, or blue light in units of subpixels on the phosphor layer.

15. The method for manufacturing a display device according to claim 9, wherein the member arranging step includes removing the wafer and arranging a phosphor sheet made of a phosphor layer converting light into red light, green light, or blue light arrayed in units of subpixels on the plurality of light-emitting elements.

16. The method for manufacturing a display device according to claim 9, wherein the member arranging step includes arranging a phosphor sheet formed of a phosphor layer converting light into red light, green light, or blue light arrayed in units of subpixels on the wafer.

17. The method for manufacturing a display device according to claim 9, wherein the substrate is a transparent substrate, and
wherein the member arranging step includes arranging a phosphor sheet including a phosphor layer converting light into red light, green light, or blue light arrayed in units of subpixels on the transparent substrate.

18. A light-emitting device comprising:
a plurality of light-emitting elements having a first face, arranged in an array formed on a wafer, and having at least one of a first electrically conducting electrode and a second electrically conducting electrode on the first face;
a substrate having an electrode corresponding to the electrode on the first face of the plurality of light-emitting elements; and
an anisotropic conductive film providing an anisotropic conductive connection between the electrode on the first face of the plurality of light-emitting elements and the electrode of the substrate.

19. A method for manufacturing a light-emitting device, comprising compression bonding a wafer on which a plurality of light-emitting elements having a first face are arrayed, the plurality of light-emitting elements having at least one of a first electrically conducting electrode and a second electrically conducting electrode on the first face, to a substrate having an electrode corresponding to the electrode on the first face of the plurality of light-emitting elements via an anisotropic conductive adhesive providing an anisotropic conductive connection between the electrode on the first face of the plurality of light-emitting elements and the electrode of the substrate.
